(19) United States
(12) Patent Application Publication
(10) Pub. No.: US 2006/0267040 A1
(43) Pub. Date: Nov. 30, 2006

(54) High-brightness LED with protective function of electrostatic discharge damage

(75) Inventors: Jong Hwan Baek, Seoul (KR); Je Myung Park, Siheung (KR); Geun Chang Ryo, Siheung (KR); Chang Wook Kim, Anyang (KR); Jun Ho Seo, Gunpo (KR); Young Jae Song, Suwon (KR)

Correspondence Address: MCDERMOTT WILL & EMERY LLP, 600 13TH STREET, N.W., WASHINGTON, DC, 20005-3096, US

(73) Assignee: Samsung Electro-Mechanics Co., Ltd.

(21) Appl. No.: 11/442,957

(22) Filed: May 31, 2006

(30) Foreign Application Priority Data
May 31, 2005 (KR) 10-2005-0046283

(51) Int. Cl. H01L 33/00

(52) U.S. Cl. 257/99

(57) ABSTRACT

The present invention relates to a high-brightness LED with a protective function of electrostatic discharge damage. The high-brightness LED with a protective function of electrostatic discharge damage includes a lead frame that is formed with a pair of anode and cathode leads; a package that is formed of synthetic resin and in which a portion of the lead frame is housed; an LED chip that is mounted on the upper surface of the lead frame inside the package; an electrostatic discharge damage protecting element that is mounted on the lower surface of the lead frame inside the package and is connected parallel to the LED chip through a wire; and a molding material that is filled in the package so as to protect the LED chip.

### CROSS-REFERENCE TO RELATED APPLICATIONS

The application claims the benefit of Korea Patent Application No. 2005-0046283 filed with the Korea Industrial Property Office on May 31, 2005, the disclosure of which is incorporated herein by reference.

### BACKGROUND OF THE INVENTION

1. Field of the Invention

The present invention relates to a high-brightness LED with a protective function of electrostatic discharge damage, and more specifically, a high-brightness LED with a protective function of electrostatic discharge damage which not only protects a light emitting diode from electrostatic discharge damage, but also enhances the brightness of the light emitting diode.

2. Description of the Related Art

In general, a light emitting diode (LED) generates minority carriers (electrons or holes) injected by using the p-n junction structure of a semiconductor, and recombines the minority carriers so as to emit light. In other words, if a forward voltage is applied to a specific element of semiconductor, electrons and holes are recombined while moving through a joined portion between an anode and cathode. Since an energy in such a state is smaller than an energy in a state where the electrons and holes are separated, light is emitted due to a difference in the energy generated at this time.

Such an LED can irradiate light with high efficiency by using a low voltage. Therefore, the LED is used in a home appliance, a remote control, an electronic display board, a marker, an automation equipment, or the like.

Particularly, as the size of telecommunication devices are reduced and compacted, resistors, condensers, noise filter, and the like which are various parts of the devices are also reduced in size. Accordingly, an LED is also formed in the form of a surface mount device (hereinafter, referred to as SMD) so as to be directly mounted on a printed circuit board (PCB).

Such an SMD-type LED package is manufactured by a top-view method or side-view method according to a use thereof. An LED is generally known to be weak in a static electricity or reverse voltage.

In order to make up for the weakness of an LED, a constant voltage diode is provided, in which an electric current can flow in the reverse direction. Preferably, in such a constant voltage diode, a Zener diode as such a constant voltage is connected parallel to an LED chip so as to effectively cope with static electricity.

Now, a high-brightness LED with a protective function of electrostatic discharge damage according to the related art will be described in detail with reference to FIGS. 1 to 2.

FIG. 1 is a front view illustrating a high-brightness LED with a protective function of electrostatic discharge damage according to the related art, and FIG. 2 is a plan cross-sectional view illustrating a high-brightness LED with a protective function of electrostatic discharge damage shown in FIG. 1.

As shown in FIGS. 1 and 2, a constant voltage diode according to the related art has a parallel structure as follows: an LED chip 30 and an electrostatic discharge damage protecting element 40 composed of a Zener diode are mounted in a line on the same surface of a lead frame 50 which is composed of a pair of anode 51 and cathode 52, and the LED chip 30 and the electrostatic discharge damage protecting element 40 are connected to each other through a wire 60 formed of gold (Au).

Reference numeral 10 represents a package formed of transparent or opaque synthetic resin, and reference numeral 20 represents a molding material for protecting the LED chip.

The Zener diode serving as the electrostatic discharge damage protecting element 40 is also referred to as a constant voltage diode. Further, the Zener diode is manufactured as one of semiconductor P-N junction diodes so that the operational characteristic thereof is shown in a breakdown region of P-N junction, and is used for a constant voltage. The Zener diode obtains a constant voltage through the Zener recovery, operates at a current of 10 mA in the P-N junction of silicon, and can obtain a constant voltage of 3 to 12V according to the type thereof.

In the light emitting diode according to the related art, such a Zener diode is connected in parallel to the LED chip through a wire. Therefore, although a reverse current is applied due to a static electricity, the Zener diode can prevent damage.

In the light emitting diode according to the related art, however, the Zener diode and the LED chip are mounted in parallel on the lead frame. Therefore, the lead frame should be large enough in order to secure a sufficient region for wire-bonding, and thus the size of the package of the light emitting diode becomes large, which makes it difficult to miniaturize the package of the light emitting diode.

Further, if the Zener diode and the LED chip are mounted in parallel on the lead frame, light emitted from the LED chip is absorbed or diffused by the Zener diode, thereby reducing the brightness of the light emitting diode. Further, the characteristic and reliability of the light emitting diode are deteriorated, and light emission efficiency is also reduced.

### SUMMARY OF THE INVENTION

An advantage of the present invention is that it provides a high-brightness LED with a protective function of electrostatic discharge damage in which an LED chip and Zener diode are connected in parallel to each other through a wire on a lead frame, the Zener diode being mounted on the rear surface of the lead frame having the LED chip formed thereon, so that the light emitting diode can be protected from an electrostatic discharge damage and the brightness of the light emitting diode can be enhanced.

Additional aspects and advantages of the present general inventive concept will be set forth in part in the description which follows and, in part, will be obvious from the description, or may be learned by practice of the general inventive concept.

According to an aspect of the invention, a high-brightness LED with a protective function of electrostatic discharge damage includes a lead frame that is formed with a pair of anode and cathode leads; a package that is formed of synthetic resin and in which a portion of the lead frame is housed; an LED chip that is mounted on the upper surface of the lead frame inside the package; an electrostatic discharge damage protecting element that is mounted on the lower surface of the lead frame inside the package and is connected parallel to the LED chip through a wire; and a molding material that is filled in the package so as to protect the LED chip.

According to another aspect of the invention, the LED chip is mounted on the upper surface of the anode lead of the lead frame, and the electrostatic discharge damage protecting element is mounted on the lower surface of the cathode lead of the lead frame.

According to a further aspect of the invention, the LED chip is mounted on the upper surface of the cathode lead of the lead frame, and the electrostatic discharge damage protecting element is mounted on the lower surface of the anode lead of the lead frame.

According to a still further aspect of the invention, the LED chip is mounted on the upper surface of the anode lead of the lead frame, and the electrostatic discharge damage protecting element is mounted on the lower surface of the anode lead of the lead frame.

According to a still further aspect of the invention, the LED chip is mounted on the upper surface of the cathode lead of the lead frame, and the electrostatic discharge damage protecting element is mounted on the lower surface of the cathode lead of the lead frame.

According to a still further aspect of the invention, the electrostatic discharge damage protecting element is formed of a constant voltage diode or varistor, and the constant voltage diode is formed of a diode selected from a group composed of a Zener diode, an avalanche diode, a switching diode, and a Schottky diode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a front view illustrating a high-brightness LED with a protective function of electrostatic discharge damage according to the related art;

FIG. 2 is a plan cross-sectional view illustrating the high-brightness LED with a protective function of electrostatic discharge damage shown in FIG. 1;

FIG. 3 is a front view illustrating a high-brightness LED with a protective function of electrostatic discharge damage according to a first embodiment of the present invention;

FIG. 4 is a plan cross-sectional view illustrating the high-brightness LED with a protective function of electrostatic discharge damage shown in FIG. 3;

FIG. 5 is a diagram schematically showing a reverse current preventing circuit of the high-brightness LED with a protective function of electrostatic discharge damage shown in FIG. 4;

FIG. 6 is a front view illustrating a high-brightness LED with a protective function of electrostatic discharge damage according to a second embodiment of the invention;

FIG. 7 is a plan cross-sectional view illustrating the high-brightness LED with a protective function of electrostatic discharge damage shown in FIG. 6;

FIG. 8 is a front view illustrating a high-brightness LED with a protective function of electrostatic discharge damage according to a third embodiment of the invention;

FIG. 9 is a plan cross-sectional view illustrating the high-brightness LED with a protective function of electrostatic discharge damage shown in FIG. 8;

FIG. 10 is a front view illustrating a high-brightness LED with a protective function of electrostatic discharge damage according to a fourth embodiment of the invention;

FIG. 11 is a plan cross-sectional view illustrating the high-brightness LED with a protective function of electrostatic discharge damage shown in FIG. 10.

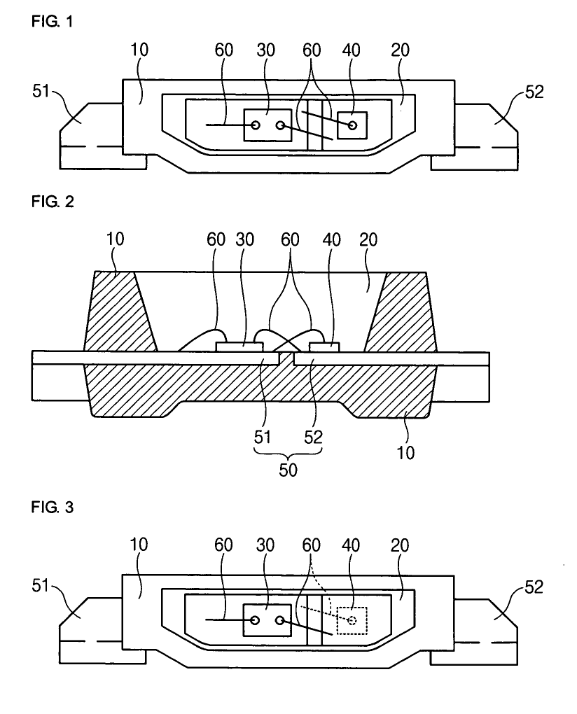

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, preferred embodiments of the present invention will be described in detail with reference to the accompanying drawings so that the present invention can be easily embodied by a person with an ordinary skill in the art.

In the drawings, the thickness is enlarged in order to clearly illustrate various layers and regions. In the entire specification, the same reference numerals are attached to the same or similar components.

Now, a high-brightness LED with a protective function of electrostatic discharge damage according to an embodiment of the invention will be described with reference to the drawings.

### First Embodiment

Referring to FIGS. 3 to 5, a high-brightness LED with a protective function of electrostatic discharge damage according to a first embodiment of the invention will be described in detail.

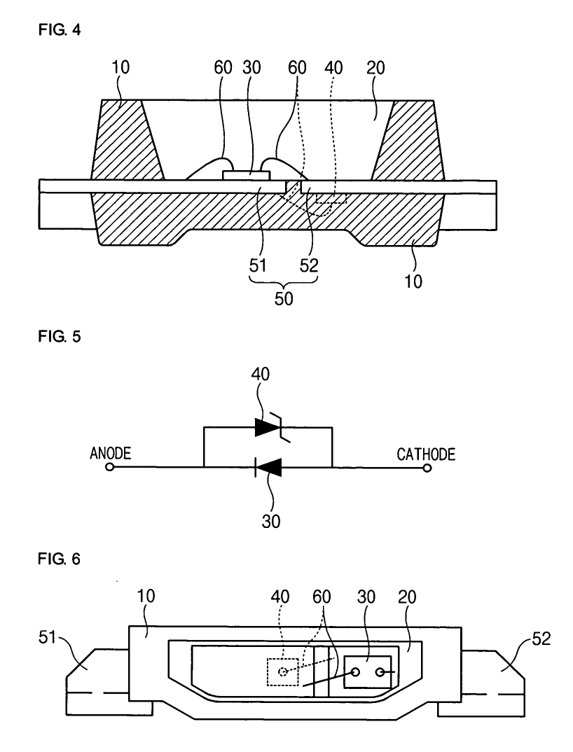

FIG. 3 is a front view illustrating the high-brightness LED with a protective function of electrostatic discharge damage according to the first embodiment of the invention. FIG. 4 is a plan cross-sectional view illustrating the high-brightness LED with a protective function of electrostatic discharge damage shown in FIG. 3. FIG. 5 is a diagram schematically showing a reverse current preventing circuit of the high-brightness LED with a protective function of electrostatic discharge damage shown in FIG. 3.

As shown in FIGS. 3 to 5, the high-brightness LED with a protective function of electrostatic discharge damage according to the first embodiment of the invention is mounted on a printed circuit board (not shown) or the like through a lead frame 50 projecting from a package 10 formed of synthetic resin, that is, an anode lead 51 and cathode lead 52.

The high-brightness LED with a protective function of electrostatic discharge is composed of a typical LED chip 30 which is provided inside the package 10 so as to irradiate light when a power supply is applied and an electrostatic discharge damage protecting element 40 which is connected parallel to the LED chip 30 so as to protect damage due to a static electricity.

The LED chip 30 according to the first embodiment of the invention is mounted on the upper surface of the anode lead 51 of the lead frame by conductive epoxy through a die bonding method. The electrostatic discharge protecting element 40 is mounted on the lower surface of the cathode lead 52 of the lead frame by the same method as in the LED chip 30.

The LED chip 30 is electrically connected to the anode lead 51 and cathode lead 52 through a wire 60, and the electrostatic discharge damage protecting element 40 is wire-bonded to the anode lead 51 through the wire 60.

The LED chip 30 and the electrostatic discharge damage protecting element 40 are connected in parallel to each other, as shown in FIG. 5.

The electrostatic discharge damage protecting element 40 is formed of a constant voltage diode or a varistor. Preferably, the constant voltage diode is formed of a diode selected from a group composed of a Zener diode, an avalanche diode, a switching diode, and a Schottky diode. In the present embodiment, a Zener diode is used as the constant voltage diode.

Reference numeral 20 which has not been described represents a molding material for protecting the LED chip.

In the high-brightness LED with a protective function of electrostatic discharge as described above, the LED chip 30 is mounted on the upper surface of the anode lead 51, the electrostatic discharge damage protecting element 40 is mounted on the lower surface of the cathode lead 52, and the LED chip 30 is connected parallel to the electrostatic discharge damage protecting element 40. Accordingly, although a reverse current is applied due to a static electricity, the current is by-passed by the electrostatic discharge damage protecting element 40 to thereby protect damage which is caused by the electrostatic discharge damage.

Particularly, the electrostatic discharge damage protecting element of the high-brightness LED with a protective function of electrostatic discharge damage is mounted on the rear surface of the emitting LED chip. In other words, with reference to the lead frame, the LED chip is mounted on the upper surface and the electrostatic damage protecting element is mounted on the lower surface. Therefore, the lead frame positioned between them serves as a barrier preventing light emitted from the LED chip from being absorbed or diffused in the electrostatic discharge damage protecting element, thereby increasing the brightness of the LED.

### Second Embodiment

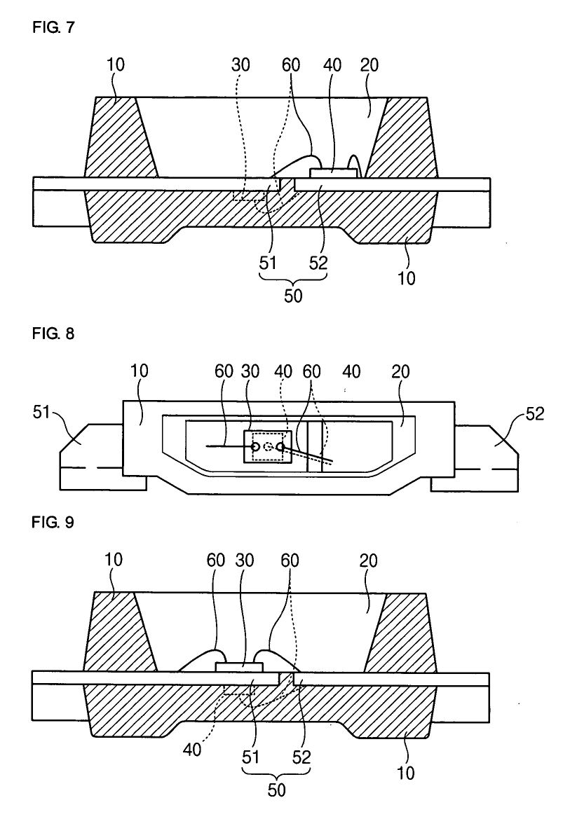

Referring to FIGS. 6 and 7, a second embodiment of the invention will be described. Here, the descriptions of the same components of the second embodiment as those of the first embodiment will be omitted. Only different components will be described.

FIG. 6 is a front view illustrating a high-brightness LED with a protective function of electrostatic discharge damage according to the second embodiment of the invention. FIG. 7 is a plan cross-sectional view illustrating the high-brightness LED with a protective function of electrostatic discharge damage shown in FIG. 6.

The high-brightness LED with a protective function of electrostatic discharge damage according to the second embodiment has almost the same construction as the high-brightness LED with a protective function of electrostatic discharge damage according to the first embodiment. As shown in FIGS. 6 and 7, however, the LED chip 30 is mounted on the upper surface of the anode lead 52, and the electrostatic discharge damage protecting element 40 is mounted on the lower surface of the cathode lead 51, which is different from the first embodiment.

As in the first embodiment, the LED chip 30 and the electrostatic discharge damage protecting element 40 are connected parallel to each other and are simultaneously present up and down with reference to the lead frame 50. Therefore, the same effect as the first embodiment can be obtained.

### Third Embodiment

Referring to FIGS. 8 and 9, a third embodiment of the invention will be described. Since most components of the third embodiment are the same as those of the first embodiment, only a different construction will be described.

FIG. 8 is a front view illustrating a high-brightness LED with a protective function of electrostatic discharge damage according to the third embodiment of the invention. FIG. 9 is a plan cross-sectional view illustrating the high-brightness LED with a protective function of electrostatic discharge damage shown in FIG. 8.

As shown in FIGS. 8 and 9, even in the high-brightness LED according to the third embodiment, the LED chip 30 and the electrostatic discharge damage protecting element 40 are connected parallel to each other and are simultaneously present up and down with reference to the lead frame 50. Therefore, the third embodiment can obtain the same operation and effect as those of the first and second embodiments.

In the high-brightness LED according to the third embodiment, however, the LED chip 30 is mounted on the upper surface of the anode lead 51, and the electrostatic discharge damage protecting element 40 is also mounted on the lower surface of the anode lead 51, which is different from the first and second embodiments.

### Fourth Embodiment

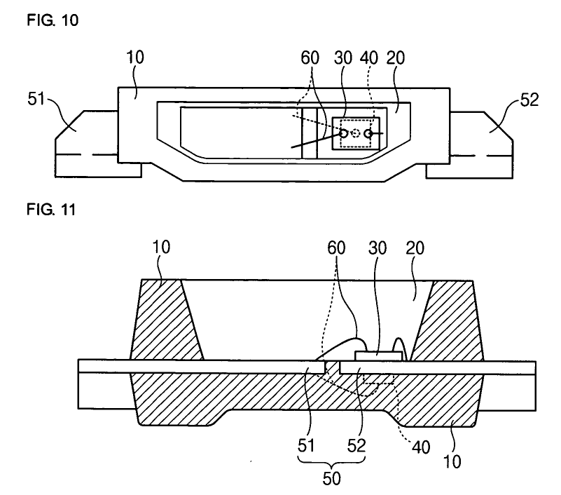

FIGS. 10 and 11 illustrate a high-brightness LED with a protective function of electrostatic discharge damage according to a fourth embodiment of the invention. As shown in FIGS. 10 and 11, the fourth embodiment has the same construction as those of the first to third embodiments in that the LED chip 30 and the electrostatic discharge damage protecting element 40 are connected parallel to each other and are simultaneously present up and down with reference to the lead frame 50. However, the LED chip 30 and the electrostatic discharge damage protecting element 40 are respectively mounted on the upper and lower surfaces of the cathode lead 52, which is different from the first to third embodiments.

Even in the fourth embodiment, the same operation and effect as those of the first to third embodiments can be obtained.

Particularly, in the high-brightness LED with a protective function of electrostatic discharge damage according to the third and fourth embodiment of the invention as described above, the LED chip and the electrostatic discharge damage protecting element are mounted on the upper and lower surfaces of the same lead frame. Therefore, the size of the lead frame can be minimized, compared with that of the high-brightness LED with a protective function of electrostatic discharge damage according to the first and second embodiments, which makes it possible to miniaturize the LED package.

While the present invention has been described with reference to exemplary embodiments thereof, it will be understood by those skilled in the art that various changes and modifications in form and detail may be made therein without departing from the scope of the present invention as defined by the following claims.

In the present invention as described above, the LED chip and the electrostatic discharge damage protecting element are connected parallel to each other and are simultaneously mounted up and down with reference to the lead frame. Therefore, although a reverse current is applied due to static electricity, the current is by-passed by the electrostatic discharge damage protecting element to thereby prevent loss which is caused by the electrostatic discharge.

Further, with reference to the lead frame, the LED chip is mounted on the upper surface and the electrostatic discharge damage protecting element is mounted on the lower surface. Therefore, the lead frame positioned between them serves to prevent light emitted from the LED chip from being absorbed or diffused by the electrostatic discharge damage protecting element, thereby increasing the same brightness of the LED.

Furthermore, the LED chip and the electrostatic discharge damage protecting element are mounted on the upper and lower surfaces of the same lead frame. Therefore, the size of the lead frame is minimized to thereby miniaturize the LED package.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A high-brightness LED with a protective function of electrostatic discharge damage comprising:
a lead frame that is formed with a pair of anode and cathode leads;
a package that is formed of synthetic resin and in which a portion of the lead frame is housed;
an LED chip that is mounted on the upper surface of the lead frame inside the package;
an electrostatic discharge damage protecting element that is mounted on the lower surface of the lead frame inside the package and is connected parallel to the LED chip through a wire; and
a molding material that is filled in the package so as to protect the LED chip.

2. The high-brightness LED with a protective function of electrostatic discharge damage according to claim 1,
wherein the LED chip is mounted on the upper surface of the anode lead of the lead frame, and the electrostatic discharge damage protecting element is mounted on the lower surface of the cathode lead of the lead frame.

3. The high-brightness LED with a protective function of electrostatic discharge damage according to claim 1,
wherein the LED chip is mounted on the upper surface of the cathode lead of the lead frame, and the electrostatic discharge damage protecting element is mounted on the lower surface of the anode lead of the lead frame.

4. The high-brightness LED with a protective function of electrostatic discharge damage according to claim 1,
wherein the LED chip is mounted on the upper surface of the anode lead of the lead frame, and the electrostatic discharge damage protecting element is mounted on the lower surface of the anode lead of the lead frame.

5. The high-brightness LED with a protective function of electrostatic discharge damage according to claim 1,
wherein the LED chip is mounted on the upper surface of the cathode lead of the lead frame, and the electrostatic discharge damage protecting element is mounted on the lower surface of the cathode lead of the lead frame.

6. The high-brightness LED with a protective function of electrostatic discharge damage according to any one of claims 1 to 5,
wherein the electrostatic discharge damage protecting element is formed of a constant voltage diode or varistor.

7. The high-brightness LED with a protective function of electrostatic discharge damage according to claim 6,
wherein the constant voltage diode is formed of a diode selected from a group composed of a Zener diode, an avalanche diode, a switching diode, and a Schottky diode.
